(19) United States
(12) Patent Application Publication
(10) Pub. No.: US 2016/0066471 A1
(43) Pub. Date: Mar. 3, 2016

(54) COOLING CONTROL OF INFORMATION TECHNOLOGY EQUIPMENT

(71) Applicant: Alibaba Group Holding Limited, George Town (KY)

(72) Inventors: Shu Zhang, Hangzhou (CN); Huahua Ren, Hangzhou (CN); Yu Han, Hangzhou (CN); Jiefu Tan, Shanghai (CN)

(21) Appl. No.: 14/841,065

(22) Filed: Aug. 31, 2015

(30) Foreign Application Priority Data
Sep. 1, 2014 (CN) 201410440237.1

(51) Int. Cl. H05K 7/20; G05D 27/02; G05D 23/19; G05B 15/02; G05D 7/06

(52) U.S. Cl. CPC H05K 7/20209; G05B 15/02; G05D 7/0617; G05D 23/1917; G05D 27/02

(57) ABSTRACT

Embodiments of the present application relate to a method, apparatus, and system for controlling cooling of equipment such as Information Technology (IT) equipment. The method includes acquiring equipment cooling status information, wherein the equipment cooling status information is collected by a set of one or more sensors included in equipment to be cooled, and sending equipment cooling information to cooling equipment to cause the cooling equipment to perform cooling control of the equipment to be cooled based at least in part on the equipment cooling information, wherein the equipment cooling information comprises at least part of the equipment cooling status information or information obtained after processing the equipment cooling status information or both.

### CROSS REFERENCE TO OTHER APPLICATIONS

This application claims priority to People's Republic of China Patent Application No. 201410440237.1 entitled A COOLING CONTROL METHOD, DEVICE, AND SYSTEM, filed Sep. 1, 2014 which is incorporated herein by reference for all purposes.

### FIELD OF THE INVENTION

The present application relates to cooling control. In particular, the present application relates to a method, system, and device for controlling cooling of electronic systems or devices.

### BACKGROUND OF THE INVENTION

The environment of an equipment room housing electronic equipment is often controlled. For example, because electronic equipment such as Information Technology (IT) equipment generates a relatively large amount of heat, the equipment room is cooled to provide a stable and reliable temperature environment for the IT equipment. As an example, the IT equipment includes servers and switches. The traditional cooling control method primarily controls cooling based on information collected by physical sensors installed on ceilings of cooling/heating aisles in the equipment room, or at air-conditioning intakes or return vents of the equipment room. The information collected by the physical sensors can include information collected by temperature sensors or information collected by pressure sensors. Because the locations at which the physical sensors are installed are often a certain distance from the IT equipment, the information, such as temperatures, collected by the physical sensors will generally deviate from the actual temperatures of the IT equipment in terms of spatial and temporal transmission. The existence of such deviation usually results in a gap between the results of cooling control based on the information collected by the physical sensors and the actual needs of the IT equipment.

Therefore, traditional methods and systems for controlling cooling are typically unable to achieve “need-based cooling.”

### BRIEF DESCRIPTION OF THE DRAWINGS

Various embodiments of the invention are disclosed in the following detailed description and the accompanying drawings.

The drawings described here are intended to further the understanding of the present application and form a part of this application. The illustrative embodiments of the present application and the descriptions thereof are intended to explain this application and do not constitute inappropriate limitation of the present application. Among the drawings:

FIG. 1 is a flowchart of a method of controlling cooling according to various embodiments of the present application.

FIG. 2 is a flowchart of a method of acquiring a mean of equipment air intake temperature values according to various embodiments of the present application.

FIG. 3 is a flowchart of a method of acquiring a maximum value of equipment air intake temperature values according to various embodiments of the present application.

FIG. 4 is a structural diagram of a cooling control device according to various embodiments of the present application.

FIG. 5 is a flowchart of a method of controlling cooling according to various embodiments of the present application.

FIG. 6 is a structural diagram of a cooling control device according to various embodiments of the present application.

FIG. 7 is a structural diagram of a cooling control system according to various embodiments of the present application.

FIG. 8 is a framework and data flow diagram of a cooling control system according to various embodiments of the present application.

FIG. 9 is a functional diagram of a computer system for controlling cooling according to various embodiments of the present application.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

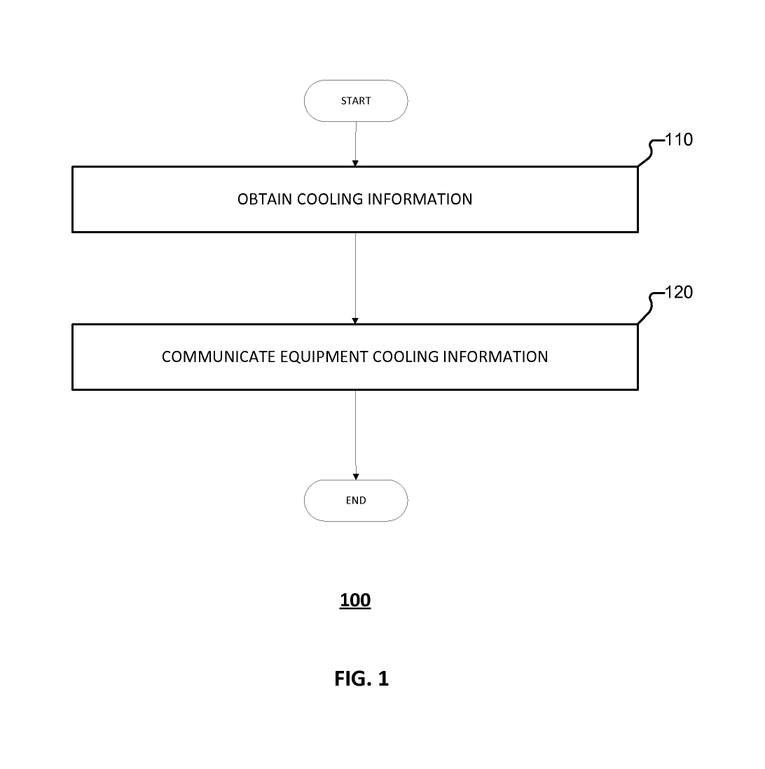

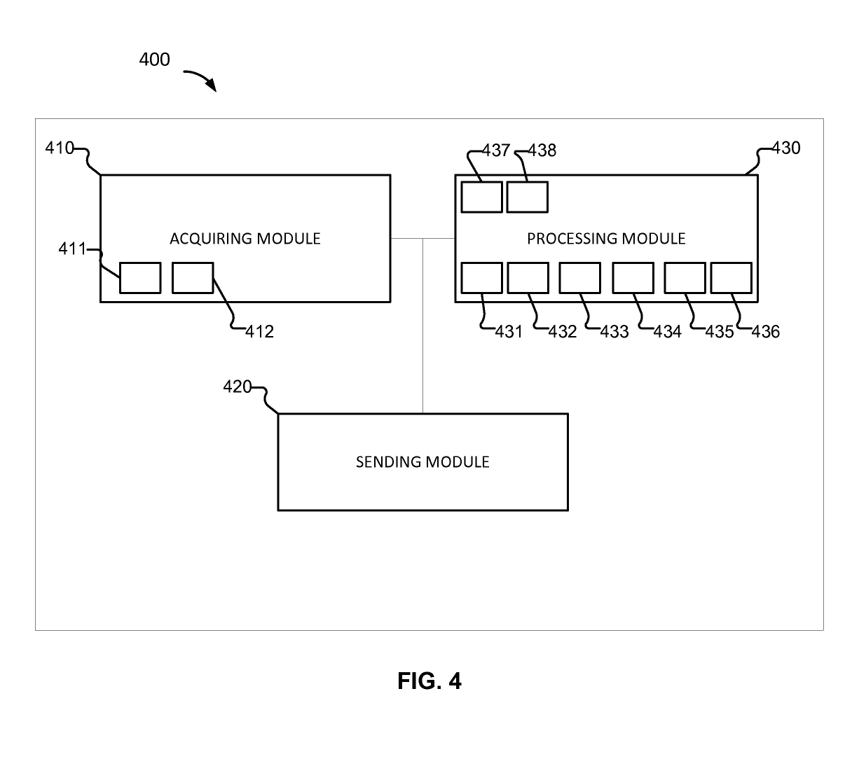

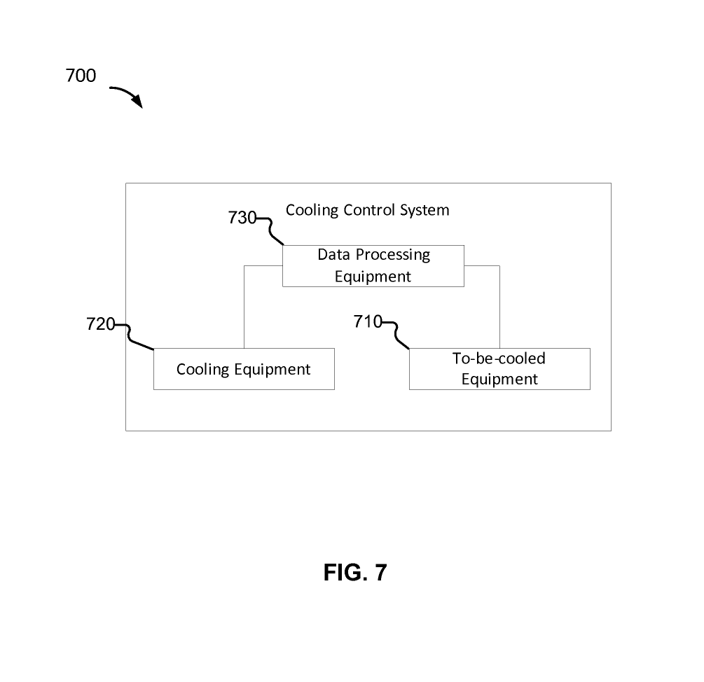

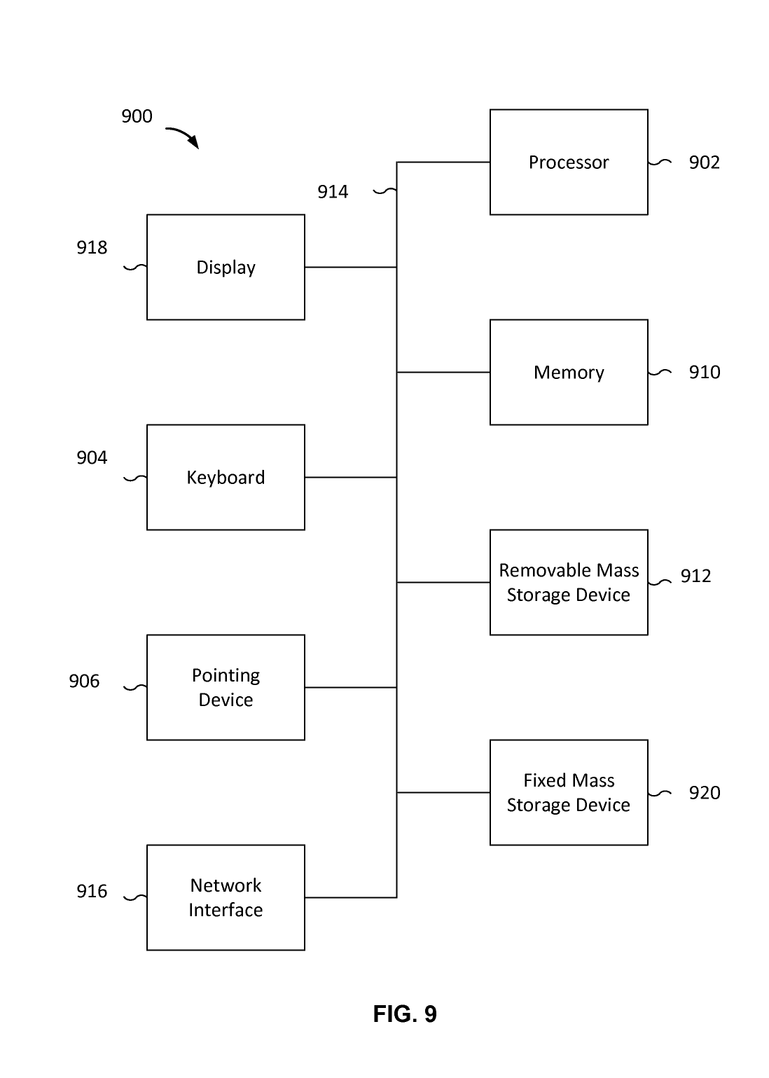

FIG. 1 is a flowchart of a method of controlling cooling according to various embodiments of the present application. Process 100 of FIG. 1 can be implemented by device 400 of FIG. 4, system 700 of FIG. 7, and/or computer system 900 of FIG. 9.

At 110, cooling status information is obtained. The cooling status information comprises equipment cooling status information. The cooling status information is acquired in real-time, periodically, or according to preset conditions (e.g., in the event that cooling satisfies a threshold level such as temperature). For example, equipment cooling status information can be acquired at fixed intervals of time. The cooling status information can comprise information that reflects the current cooling status (e.g., needs) of equipment. According to various embodiments, the equipment to which the cooling status information relates corresponds to electronic equipment such as Information Technology (IT) equipment. The IT equipment can include a server, a data storage unit, a computer, a networking equipment such as a switch, a router, the like, or any combination thereof.

According to various embodiments, the cooling status information is obtained using one or more sensors that acquire information relating to the environment in which the IT equipment is located, or that acquire information relating specifically to the cooling of the IT equipment (e.g., a temperature of the IT equipment itself or the like, rather than the surrounding environment). The cooling status information can be acquired via a sensor connected, or integrated with, the equipment. For example, the sensor used to acquire the cooling status information can be a sensor comprised in the equipment (e.g., the equipment's own sensor). In some embodiments, sensors include sensors that detect air temperatures, wind speeds (e.g., a flow rate of air) or the like. For example, the sensors can include an air temperature sensor that detects the temperature of air flowing in/out of the device, or in proximity to the motherboard of the device, or in proximity of the CPU, HDD, DIMM, or PR.

The cooling status information can indicate a status of the equipment pertaining to the cooling of the equipment contemporaneous with the time at which the cooling status information is obtained (e.g., acquired via the one or more sensors).

In some embodiments, the equipment cooling status information comprises equipment air intake temperature values, equipment airflow needs, equipment power consumptions, or the like. The equipment airflow needs can correspond to a desired amount of airflow corresponding to the equipment. The equipment airflow needs can be configurable according to settings or preferences that are set by a user such as an administrator or manufacturer of the equipment. The equipment cooling status information can be information that directly reflects the current cooling status of the equipment. In some embodiments, measurements (e.g., measured values corresponding to the equipment cooling status information is compared to one or more threshold values. The threshold values can be configurable by a user, an administrator, a manufacturer of the equipment, or the like. The equipment airflow needs can determined by obtaining equipment fan speed, air flow through the rotational speed compared with the amount of wind demand access of the equipment.

At 120, equipment cooling information is communicated. The equipment cooling information can be sent to cooling equipment. The cooling equipment can include a device that controls one or more cooling fans, a cooling coil, or the like. The equipment cooling information can instruct the cooling equipment to perform cooling functions such as circulating cold air and/or fluid around the equipment to be cooled (e.g., the IT equipment) to bring down the temperature of the latter. The equipment cooling information can correspond to a need for equipment cooling. In some embodiments, the cooling equipment can include refrigeration equipment. According to various embodiments, various cooling methods use various cooling equipment (or devices). The cooling equipment can include vapor compression refrigeration, such as equipment with a compressor, a condenser, a chiller, an evaporator, and a throttle.

In response to receiving the equipment cooling information, the cooling equipment carries out cooling control of the equipment in accordance with the equipment cooling information.

According to various embodiments, the equipment cooling information comprises the equipment cooling status information, or information obtained after processing the equipment cooling status information.

According to various embodiments, the obtaining of the equipment cooling status information comprises acquiring the equipment cooling status information collected by the corresponding equipment's own sensors. In the case of IT equipment, such as servers, examples of the equipment's own sensors include intake/outlet temperature sensors mounted on motherboards, sensors that are included with equipment such as Central Processing Units (CPUs), Hard Disk Drives (HDDs), Virtual Reality (VR) processors, and Dual-Inline-Memory-Modules (DIMMs), and sensors that obtain airflows based on “rotation speed airflow” test data fits (e.g., correlations, mappings, or the like). Various embodiments collect equipment cooling status information which can more directly reflect the equipment's cooling needs using the equipment's own sensors.

With regard to equipment airflow needs and equipment power consumptions, the equipment airflow needs and equipment power consumptions of all equipment (e.g., all the devices) within the cooling equipment cooling control range can be acquired. It is also possible to acquire the equipment airflow needs and equipment power consumptions of a portion of the equipment within the cooling equipment cooling control range. In such a case, the equipment airflow needs and equipment power consumptions of this portion of the equipment may serve as the basis for calculating the equipment airflow needs and equipment power consumptions of all the equipment. For example, the equipment airflow needs and equipment power consumptions of this portion can be extrapolated to compute the equipment airflow needs and equipment power consumptions of all the equipment. The equipment airflow needs may be obtained first by acquiring equipment fan speeds and then determining the relationship between fan speeds and airflows. In some embodiments, a mapping of fan speeds and airflows (e.g., airflow rates measured in volume of air per second) is stored in a table or other data structure stored locally at cooling equipment, equipment that provides instructions to the cooling equipment, or the like, or stored at a remote storage that is accessible to the cooling equipment or equipment that provides instructions to the cooling equipment, or the like. Accordingly, the equipment airflow needs can be obtained by acquiring the equipment fan speeds and using the acquired equipment fan speeds to look up the corresponding airflow in the mapping of fan speeds and airflows.

In some embodiments, equipment air intake temperature values can be acquired by temperature sensors on equipment located within the cooling equipment cooling control range. The measurements of these temperature sensors are the equipment air intake temperature values. As an example, the cooling equipment cooling control range can include a plurality of IT devices or the like. The cooing equipment cooling control range can correspond to a predefined area or region including a plurality of IT devices or a predefined set of devices that a cooling unit is responsible (e.g., used) for cooling. A cooling equipment cooling control range can include IT equipment cooling station N, N sets of IT equipment for the refrigeration range of refrigeration equipment. A cooling equipment cooling control range can include a refrigeration device within a region, wherein the refrigeration device is responsible (e.g., used) for all refrigeration equipment in the region of refrigeration equipment for the cooling range.

In some embodiments, equipment air intake temperature values can be acquired by acquiring air intake temperature values of a portion of the equipment within the cooling equipment cooling control range. The air intake temperature values of the portion of the equipment can be extrapolated to determine the equipment air intake temperature values corresponding to more than the portion of the equipment (e.g., all of the equipment).

In some embodiments, the portion of equipment comprises equipment in different equipment zones within the cooling equipment cooling control range. In the event the equipment air intake temperature values can be acquired by acquiring air intake temperature values of a portion (e.g., a subset) of the equipment within the cooling equipment cooling control range, the equipment air intake temperature value of at least one piece of equipment may be selected and acquired from a different equipment zone, and the equipment air intake temperature value of the at least one piece of equipment is used as a representative value of the equipment air intake temperature values in the corresponding equipment zone (e.g., the current equipment zone being measured).

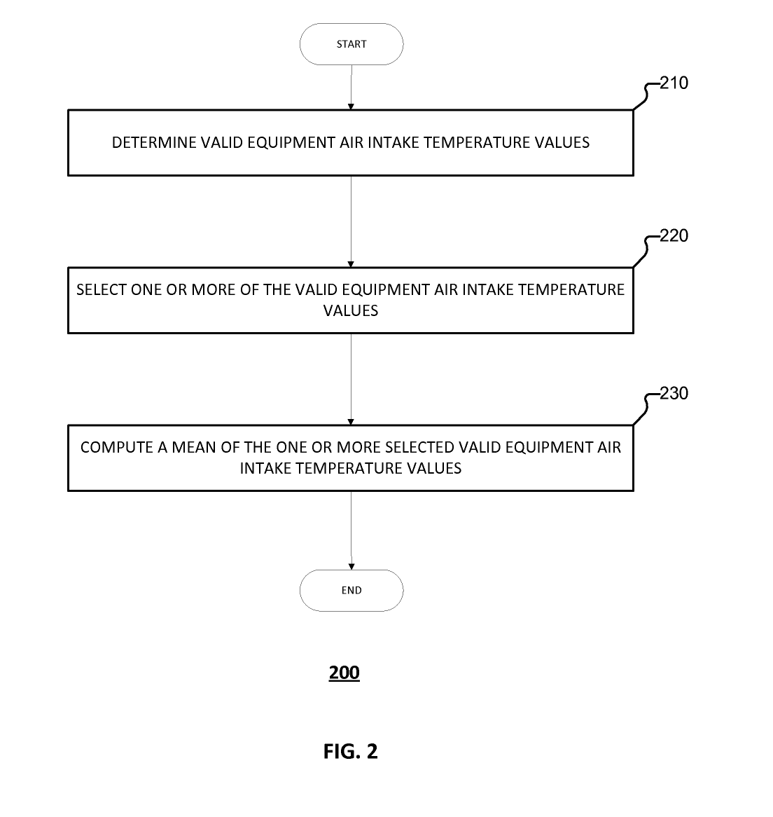

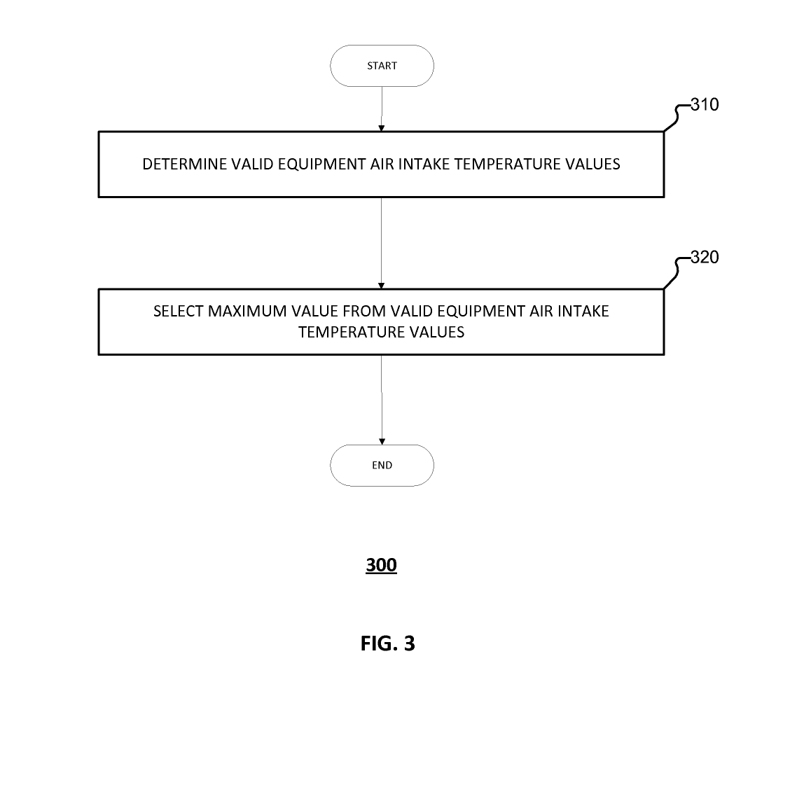

The equipment cooling information is communicated. The equipment cooling information can be communicated using various communication protocols such as TCP/IP, Modbus, Bacnet, or the like. In some embodiments, the equipment cooling information is sent to the cooling equipment. The equipment cooling information can include equipment cooling status information, or information obtained after processing the equipment cooling status information. In some embodiments, the equipment cooling status information collected by the equipment's own sensors can be directly sent to the cooling equipment. In some embodiments, the equipment cooling status information collected by the equipment's own sensors is received by the sensor's driver or firmware, which is programmed to send, via a bus or other connection to a communication interface on the equipment, the status information to the cooling equipment over a direct connection such as Bluetooth, WiFi Direct, or Infrared, over a network such as a local network, a wireless network, a wired network, the like, or any combination thereof. In some embodiments, the equipment cooling status information collected by the sensors is sent by the sensor's driver or firmware to the device's operating system, which is programmed to send the data to a communication interface on the equipment, which in turn sends the data to the cooling equipment via a direct connection. The cooling status information can be sent to the cooling equipment after the cooling status information is processed. Methods of processing cooling status information are described in connection with FIGS. 2 and 3.

According to various embodiments, after equipment air intake temperature values are acquired, air intake temperature values to be sent to the cooling equipment can be selected from among the acquired equipment air intake temperature values.

FIG. 2 is a flowchart of a method of acquiring the mean of equipment air intake temperature values according to various embodiments of the present application. Process 200 of FIG. 2 can be implemented by device 400 of FIG. 4, system 700 of FIG. 7, and/or computer system 900 of FIG. 9. Process 200 can be implemented in connection with process 100 of FIG. 1.

At 210, one or more valid equipment air intake temperature values are determined from among the acquired equipment air intake temperature values. A subset of the acquired equipment air intake temperature values can be deemed to be valid equipment air intake temperature values.

In some embodiments, the determining of valid equipment air intake temperature values comprises determining a set of valid equipment air intake temperature values that do not correspond to abnormal equipment values from among all of the acquired equipment air intake temperature values. For example, the determining of valid equipment air intake temperature values can comprise searching (e.g., identifying) among the acquired equipment air intake temperature values for abnormal equipment air intake temperature values (e.g., overly high or overly low values that are due to sensor malfunction or other equipment malfunctions), eliminating (e.g., discounting) the abnormal equipment air intake temperature values, and determining that the remaining equipment air intake temperature values are valid after eliminating the abnormal equipment air intake temperature values from a set of the acquired equipment air intake temperature values.

In some embodiments, abnormal equipment air intake temperature values comprise equipment air intake temperature values higher than the equipment air intake temperature value upper threshold, and/or equipment air intake temperature values lower than the equipment air intake temperature value lower threshold. For example, assuming that the upper threshold for equipment air intake temperature is 40° C. and that the lower threshold for equipment air intake temperature is 20° C., equipment air intake temperature values that are higher than 40° C. and lower than 20° C. are deemed to be abnormal equipment air intake temperature values. According to this example, in the event that the acquired equipment air intake temperature value is 45° C., the equipment air intake temperature value is determined to be an abnormal equipment air intake temperature value.

In some embodiments, abnormal equipment air intake temperature values are determined in connection with determining whether any of the acquired equipment air intake temperature values are statistical outliers relative to the set of acquired equipment air intake temperature values. A statistical outlier among the acquired equipment air intake temperature values can be deemed an abnormal equipment air intake temperature value. A statistical outlier among the acquired temperature air intake temperature values can be a value that does not fit a model comprising a subset of the acquired temperature air intake temperature values.

After the abnormal equipment air intake temperature values are determined, the abnormal equipment air intake temperature values are eliminated, and the equipment air intake temperature values remaining following elimination of the abnormal equipment air intake temperature values from the equipment air intake temperature values that were acquired are deemed to be valid equipment air intake temperature values.

The abnormal equipment air intake temperature values might be the result of equipment air intake temperature abnormalities arising from a specific cause and not the result of inadequate cooling by the cooling equipment or of cooling overload. Examples of a specific cause of the abnormal equipment air intake temperature values might be equipment fan failure and/or failure of the equipment's own sensor. An equipment air intake temperature abnormality arising from a specific cause does not indicate the actual cooling needs of the other equipment. Accordingly, temperature values corresponding to the equipment air intake temperature abnormalities do not need to be sent to the cooling equipment. Indeed, such equipment air intake temperature abnormalities can obscure the actual cooling needs of the other equipment. Therefore, the abnormal equipment air intake temperature values are eliminated from consideration of the actual cooling needs of the other equipment. For example, the abnormal equipment air intake values are not included in a computation of the actual needs of the other equipment.

In some embodiments, before eliminating the abnormal equipment air intake temperature value, the equipment failure corresponding to the abnormal equipment air intake temperature value is determined. For example, a determination of whether the equipment failure is a failure of the equipment's own sensor, an equipment fan failure, or the like is made by sending a pre-specified health status inquiry message to the sensor, the fan, and/or their device drivers. A failure response or a lack of response within a certain amount of time both indicates failure. In some embodiments, in the event that an equipment air intake temperature abnormality does not result from a failure of the equipment's own sensor or an equipment fan failure, then the corresponding abnormal equipment air intake temperature value need not be eliminated. For example, if an equipment air intake temperature abnormality does not result from a failure of the equipment's own sensor or an equipment fan failure, then the corresponding abnormal equipment air intake temperature value is not eliminated from consideration of the actual cooling needs of the other equipment, from the computation of the actual needs of the other equipment, a set of temperature values corresponding to the determined valid equipment air intake temperature values, or the like.

At 220, one or more of the valid equipment air intake temperature values is selected. In some embodiments, a threshold number of the valid equipment air intake temperature values is selected. The threshold number can correspond to a preset percentage of the equipment air intake temperature values, a preset percentage of the valid equipment air intake temperature values, or the like. In some embodiments, a specific percentage of equipment air intake temperature values is selected according to a high-to-low temperature order. For example, equipment air intake temperature values having relatively higher temperatures are selected before equipment air intake temperature values having relatively lower temperatures.

In some embodiments, one or more relatively higher temperature values are selected from valid equipment air intake temperature values.

In some embodiments, the selecting of the one or more of the valid equipment air intake temperature values comprises ranking the valid equipment air intake temperature in a high-to-low temperature order, and selecting a threshold number (e.g., a specific percentage) of equipment air intake temperature values. For example, twenty percent of equipment air intake temperature values are selected in high-to-low temperature order, thirty percent of equipment air intake temperature values are selected in high-to-low temperature order, or forty percentage of equipment air intake temperature values are selected in high-to-low temperature order, or the like.

At 230, a mean of the one or more selected valid equipment air intake temperature values is computed. In some embodiments, another statistical representative number is computed. For example, a median of the one or more selected valid equipment air intake temperature values is computed.

In some embodiments, the calculated mean of the specific percentage of equipment air intake temperature values that were selected is used as a representative value for equipment air intake temperature values. In some embodiments, the representative value for the equipment air intake temperature values is used in connection with controlling cooling of the equipment. In some embodiments, the representative value for the equipment air intake temperature values can be compared to a threshold value, and the cooling of the equipment can be controlled based at least in part on the comparison of the representative value for the equipment air intake temperature values with the threshold value.

In some embodiments, the representative value for the equipment air intake temperature values is used in connection with controlling cooling of the equipment. In some embodiments, the representative value for the equipment air intake temperature values (e.g., the mean that was calculated from the equipment air intake temperature values) is sent to the cooling equipment. In some embodiments, the mean of higher equipment air intake temperature values (e.g., the mean of those temperature values that are higher than the upper threshold) is sent to the cooling equipment. For safety reasons such as overeating and equipment failure, the mean of the higher equipment air intake temperature values is sent to the cooling equipment.

FIG. 3 is a flowchart of a method of acquiring a maximum value of equipment air intake temperature values according to various embodiments of the present application. Process 300 of FIG. 3 can be implemented by device 400 of FIG. 4, system 700 of FIG. 7, and/or computer system 900 of FIG. 9. Process 300 can be implemented in connection with process 100 of FIG. 1.

At 310, valid equipment air intake temperature values are determined. For example, the valid equipment air intake temperature values are determined from among the acquired equipment air intake temperature values. The valid equipment air intake temperature values can be determined in a similar manner as the determination of the valid equipment air intake temperature values described in relation to process 200 of FIG. 2.

At 320, a maximum value is selected from among the valid equipment air intake temperature values. For example, the maximum value from the valid equipment air intake temperature values is acquired. The maximum value can correspond to the valid equipment air intake temperature value corresponding to the highest temperature from among the valid equipment air intake temperature values. The maximum value can be used in connection with controlling cooling of the equipment.

In some embodiments, the maximum value is selected from among the valid equipment air intake temperature values and used as a representative value of the equipment air intake temperature values. The maximum value among the valid equipment air intake temperature values that were acquired is then sent to the cooling equipment. The cooling equipment can use the maximum value in connection with controlling the cooling of the equipment. For example, the cooling equipment can receive the maximum value as a parameter, determine the difference between the maximum value and the target temperature value, and perform an appropriate amount of cooling operation to reach the target temperature value.

In practice, airflow leaks, non-uniformities in airflow structures, and other such problems are present during cooling. According to various embodiments, processing of the acquired equipment airflow needs comprises revising the acquired equipment airflow needs to obtain revised equipment airflow needs. The revising of the acquired equipment airflow needs can comprise multiplying the equipment airflow needs by a safety factor greater than 1. For example, the safety factor could be empirically determined to be 1.1, 1.3, or the like. The safety factor can be set by an administrator, a user, a manufacturer of the cooling system, or the like. Thereafter, the revised equipment airflow needs are sent. For example, the revised equipment airflow needs can be sent to a device or system configured to control cooling of the equipment. The revised airflow needs can be sent to the cooling equipment (e.g., the device or system configured to control cooling of the equipment) via a network connection or a direct connection.

In some embodiments, the sum of the revised airflow needs can be sent in connection with the sending of the equipment airflow needs. In some embodiments, the equipment airflow needs collected by the equipment's own sensors are sent and the revising is performed by the cooling equipment.

In some embodiments, measurements associated with equipment power consumptions are sent to the cooling equipment. For example, the equipment power consumptions can be measured by the equipment's operating system or other application, and sent to the cooling equipment. The acquired equipment power consumptions can be sent to the cooling equipment without prior processing of the acquired equipment power consumptions.

In some embodiments, the processing of the acquired equipment power consumption comprises calculating the percentage of increases in equipment power consumption of equipment (e.g., all equipment or a portion of equipment) within the cooling equipment cooling control range. The percentage of increases in the equipment power consumption of the equipment within the equipment cooling range can be computed according to Equation (1).

$${P}_{Increase} = \frac{{P}_{Current} - {P}_{Previous}}{{P}_{Previous}} \times 100 \% \qquad ( 1 )$$

Referring to Equation (1), P_{Increase} refers to the percentage increase in equipment power consumption, P_{Current} refers to the current equipment power consumption, and P_{Previous} refers to a previous power consumption measured at a previous measurement time.

In some embodiments, the equipment power consumptions are acquired at fixed intervals of time or at preset times. Because the equipment power consumptions can be acquired at fixed intervals of time, the percentage increase in equipment power consumption can be calculated contemporaneously with the acquisition of the equipment power consumption. An increase in equipment power consumption indicates that the equipment air intake temperature will rise.

In some embodiments, the processing of the acquired equipment power consumption comprises selecting power consumption percentage increases for a specific percentage (e.g., a threshold percentage) of equipment in high-to-low order of the percentage increases in equipment power consumption.

In some embodiments, only the equipment power consumption percentage increases of equipment with higher power consumption percentage increases (e.g., equipment whose power consumption percentage increases are greater than a percentage increase threshold) are sent. Depending on implementation, the threshold can be set to 30%, 40%, 50%, or the like.

In some embodiments, the equipment cooling need information of different equipment zones can be sent in connection with sending the equipment cooling need information to the cooling equipment. The equipment cooling need information of information of the different equipment zones can be sent to the cooling equipment in the corresponding equipment zones in accordance with the correspondences between equipment zones and cooling equipment zones. For example, the equipment can be partitioned into different zones in accordance with the equipment zones affected by the cooling equipment cooling and can establish correspondences between equipment zones and cooling equipment zones. A mapping of zones and corresponding equipment in the zones can be stored in a table or other data structure. The mapping can be stored locally or in a database that is accessible via remote access. The equipment cooling need information of different equipment zones can be sent to cooling equipment in the corresponding equipment zones.

In some embodiments, cooling equipment can perform cooling operations based on equipment cooling need information being sent (e.g., fed back) to the cooling equipment. For example, the cooling equipment can carry out cooling control in accordance with the equipment cooling need information. Because the cooling need information comprises equipment cooling status information or information obtained after processing the equipment cooling status information, and because equipment cooling status information comprises the equipment cooling status information collected by the equipment's own sensors, the cooling need information can therefore reflect the cooling needs of equipment directly and in real time. Accordingly, cooling control that is based on the equipment cooling need information can achieve need-based cooling.

According to various embodiments, because the equipment's own sensors collect the equipment cooling status information, additional physical cables and additional sensors are not required. As a result, cooling systems used in connection with controlling cooling equipment are not unnecessarily limited by spatial restrictions. In some embodiments, the equipment's own sensors are evenly distributed together with the equipment in the cooling area. Therefore, the equipment cooling status information collected by the equipment's own sensors has good spatial granularity and uniformity. For example, the equipment cooling status information provides an accurate representation of the temperatures or cooling needs of the equipment. Therefore, performing cooling control based on the equipment cooling statuses collected by the equipment's own sensors both saves costs and can achieve control of final cooling supply by final cooling need feedback.

The cooling control can be performed by the equipment or by a third party terminal that is independent of the equipment. For example, process 100, process 200, or process 300 can be performed by the equipment or by a terminal that is separate from the equipment.

According to various embodiments, the elements of process 100, process 200, or process 300 can be performed by the same device, or by different devices.

FIG. 4 is a structural diagram of a cooling control device according to various embodiments of the present application. Device 400 can implement process 100 of FIG. 1, process 200 of FIG. 2, and/or process 300 of FIG. 3. Device 400 can be implemented by system 700 of FIG. 7. In some embodiments, device 400 can be implemented by, or integrated with, computer system 900 of FIG. 9.

Device 400 includes an acquiring module 410, a sending module 420, and a processing module 430.

The acquiring module 410 is configured to acquire cooling status information. In some embodiments, the acquiring module 410 is configured to receive (e.g., obtain) the cooling status information from the one or more sensors. The cooling status information comprises equipment cooling status information. The cooling status information is acquired in real-time, periodically, or according to preset conditions (e.g., in the event that cooling satisfies a threshold level such as temperature). According to various embodiments, the equipment to which the cooling status information relates corresponds to electronic equipment such as Information Technology (IT) equipment.

The cooling status information acquired by the acquiring module 410 can comprise equipment air intake temperature values, equipment airflow needs, equipment power consumptions, the like, or any combination thereof. The equipment cooling status information can be information that directly reflects the current cooling status of the equipment.

The acquiring module 410 can acquire the equipment cooling status information of the equipment collected by the equipment's own sensors. Because the equipment includes the sensors, the acquiring module 410 acquires equipment cooling status information which can directly reflect the equipment's cooling needs.

The acquiring module 410 can acquire the equipment airflow needs and equipment power consumptions of all equipment within the cooling equipment cooling control range in connection with the acquiring module 410 acquiring equipment airflow needs and equipment power consumptions. In some embodiments, the acquiring module 410 acquires the equipment airflow needs and equipment power consumptions of a subset of all the equipment within the cooling equipment cooling control range.

In some embodiments, the acquiring module 410 includes a first acquiring sub-module 411 and a second acquiring sub-module 412. The first acquiring sub-module 411 and the second acquiring sub-module can acquire equipment air intake temperature values. The first acquiring sub-module 411 is configured to acquire all equipment air intake temperature values within the cooling equipment cooling control range. The second acquiring sub-module 412 is configured to acquire air intake temperature values within the cooling equipment cooling control range for a subset of equipment. The subset of the equipment comprises equipment in different zones within the cooling equipment cooling control range.

The sending module 420 is configured to send equipment cooling need information. The sending module 420 can send equipment cooling need information to cooling equipment. In some embodiments, the sending module 420 sends the equipment cooling need information so as to cause the cooling equipment to carry out cooling control of the equipment according to the equipment cooling need information. The equipment cooling need information can comprise equipment cooling status information, or information obtained after processing the equipment cooling status information.

In some embodiments, the sending module 420 can send the equipment cooling need information of different equipment zones to cooling equipment in the corresponding equipment zones. For example, the sending module 420 can send the equipment cooling need information of different equipment zones to cooling equipment in the corresponding equipment zones in accordance with the correspondences between equipment zones and cooling equipment zones. The equipment can be partitioned into different zones in accordance with the equipment zones affected by the cooling equipment cooling and can establish correspondences between equipment zones and cooling equipment zones. A mapping of zones and corresponding equipment in the zones can be stored in a table or other data structure. The mapping can be stored locally or in a database that is accessible via remote access. The sending module 420 sends equipment cooling need information acquired in different equipment zones to cooling equipment in the corresponding zones.

The processing module 430 is configured to process the equipment cooling status information. In some embodiments, the processing module 430 includes a first determining sub-module 431, a first selecting sub-module 432, and a first calculating sub-module 433. The processing module 430 can process the equipment air intake temperature values.

The first determining sub-module 431 is configured to determine a valid equipment air intake temperature value. For example, the first determining sub-module 431 determines the one or more valid equipment air intake temperature values from among the acquired equipment air intake temperature values. The first determining sub-module 431 can determine the valid equipment air intake temperature values according to process 200 of FIG. 2 or process 300 of FIG. 3. The first selecting sub-module 432 is configured to select one or more of the valid equipment air intake temperature values. In some embodiments, a threshold number of the valid equipment air intake temperature values is selected. The threshold number can correspond to a preset percentage of the equipment air intake temperature values, a preset percentage of the valid equipment air intake temperature values, or the like. In some embodiments, a specific percentage of equipment air intake temperature values are selected according to a high-to-low temperature order. For example, equipment air intake temperature values having relatively higher temperatures are selected before equipment air intake temperature values having relatively lower temperatures.

The first calculating sub-module 433 is configured to compute a mean of the one or more selected valid equipment air intake temperate values. The first calculating sub-module 433 can calculate the mean of the specific percentage of equipment air intake temperature values that were selected by the first selecting sub-module 432. In some embodiments, the first calculating sub-module 433 computes another statistical representative number. For example, the first calculating sub-module 433 calculates a median of the one or more selected valid equipment air intake temperature values is computed.

In some embodiments, the calculated mean of the specific percentage of equipment air intake temperature values that were selected is used as a representative value for equipment air intake temperature values. In some embodiments, device 400 uses the representative value for the equipment air intake temperature values in connection with controlling cooling of the equipment. In some embodiments, the representative value for the equipment air intake temperature values can be compared to a threshold value, and the cooling of the equipment can be controlled based at least in part on the comparison of the representative value for the equipment air intake temperature values with the threshold value.

In some embodiments, the processing module 430 comprises a second determining sub-module 434 and a second selecting sub-module 435. The processing module 430 can use the second determining sub-module 434 and the second selecting sub-module 435 in connection with processing equipment air intake temperature values.

The second determining sub-module 434 is configured to determine valid equipment air intake temperature values. For example, the valid equipment air intake temperature values are determined from among the acquired equipment air intake temperature values. The valid equipment air intake temperature values can be determined in a similar manner as the determination of the valid equipment air intake temperature values described in relation to process 200 of FIG. 2.

The second determining sub-module 434 is configured to select a maximum from among the valid equipment air intake temperature values. The maximum value can correspond to the valid equipment air intake temperature value corresponding to the highest temperature from among the valid equipment air intake temperature values. Device 400 can use the maximum value in connection with controlling cooling of the equipment.

In some embodiments, the processing module 430 comprises a revising sub-module 436. The processing module 430 can process equipment airflow needs.

The revising sub-module 436 is configured to revise equipment airflow needs that were acquired and obtain revised equipment airflow needs. In some embodiments, the revising sub-module 436 revises the equipment airflow needs by multiplying the equipment airflow needs by a safety factor greater than 1. The revised equipment airflow needs can be sent to a device or system configured to control cooling of the equipment.

Because actual environments comprising equipment that is to be cooled comprise airflow leaks, non-uniformities of airflow structures, and other such problems, the revising sub-module 436 revises the equipment airflow needs that are acquired.

The sending module 420 can send measurements associated with equipment power consumption. The sending module 420 can send acquired equipment power consumptions. The acquired equipment power consumptions can be sent to the cooling equipment without prior processing of the acquired equipment power consumptions. For example, the sending module 420 can directly send the equipment power consumptions of equipment within the cooling equipment cooling control range as acquired by the acquiring module 410 to the cooling equipment. In some embodiments, the sending module 420 sends equipment consumptions that were processed by the processing module 430.

In some embodiments, the processing module 430 includes a second calculating sub-module 437 and a third selecting sub-module 438.

The second calculating sub-module 437 is configured to calculate the percentage of increases in equipment power consumption of equipment within the cooling equipment cooling control range. The second calculating sub-module 437 can compute the percentage of increases in the equipment power consumption of the equipment within the equipment cooling range according to Equation (1).

The third selecting sub-module 438 is configured to select power consumption percentage increases for a specific percentage (e.g., a threshold percentage) of equipment in high-to-low order of the percentage increases in power consumption.

The sending module 420 can send the equipment cooling status information acquired by the acquiring module 410 to the cooling equipment. The sending module 420 can also send information obtained from processing the equipment cooling status information to the cooling equipment.

In some embodiments, the cooling control device is located on the same physical entity as the equipment in the cooling equipment cooling control range. In some embodiments, the cooling device is located on a physical entity that is independent of the equipment in the cooling equipment cooling control range.

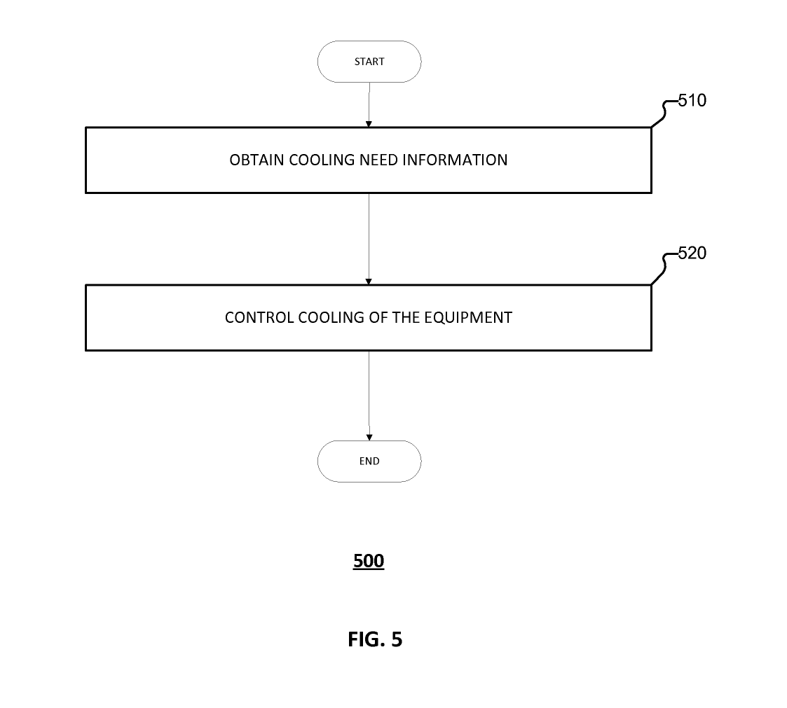

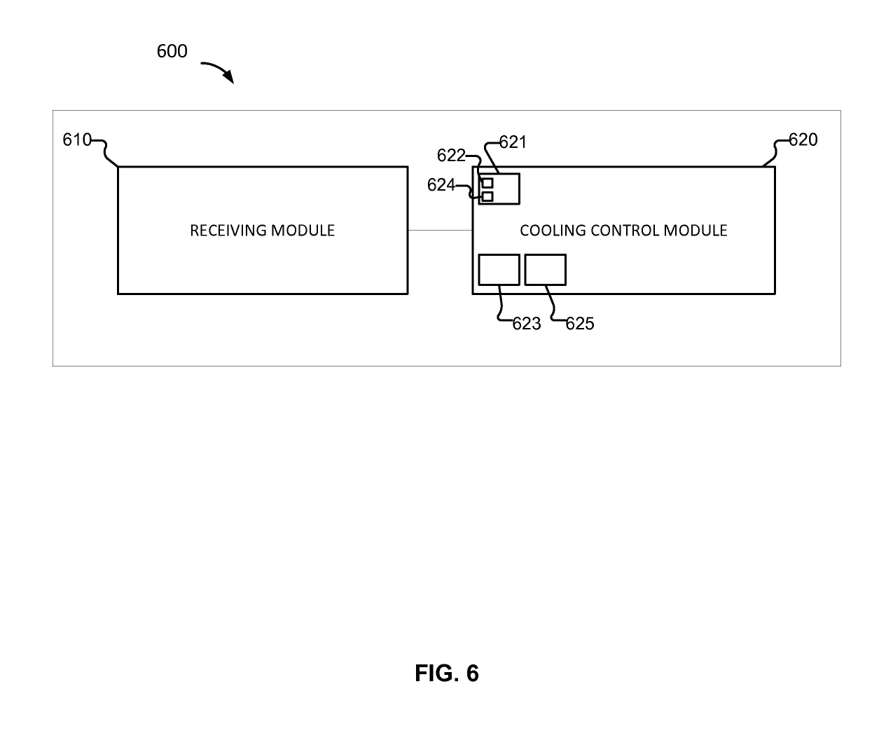

FIG. 5 is a flowchart of a method of controlling cooling according to various embodiments of the present application. Process 500 of FIG. 5 can be implemented by device 600 of FIG. 6, system 700 of FIG. 7, and/or computer system 900 of FIG. 9.

At 510, cooling information is obtained. The cooling information comprises equipment cooling information. In some embodiments, the equipment cooling information comprises cooling status information. The cooling status information is acquired in real-time, periodically, or according to preset conditions (e.g., in the event that cooling satisfies a threshold level such as temperature). For example, equipment cooling status information can be acquired at fixed intervals of time. The cooling status information can comprise information that reflects the current cooling status (e.g., needs) of equipment. According to various embodiments, the equipment to which the cooling status information relates corresponds to electronic equipment such as Information Technology (IT) equipment. The IT equipment can include a server, a data storage unit, a computer, a switch, a router, the like, or any combination thereof.

According to various embodiments, the cooling status information is obtained using one or more sensors that acquire information relating to the environment in which the IT equipment is located, or that acquire information relating specifically to the cooling of the IT equipment (e.g., a temperature of the IT equipment itself or the like, rather than the surrounding environment). The cooling status information can be acquired via a sensor connected, or integrated with, the equipment. For example, the sensor used to acquire the cooling status information can be a sensor comprised in the equipment (e.g., the equipment's own sensor).

The cooling status information can indicate a status of the equipment or the cooling of the equipment contemporaneous with the time at which the cooling status information is obtained (e.g., acquired via the one or more sensors).

The cooling status information can comprise equipment cooling status information, information obtained after processing the equipment cooling status information, or the like. The equipment cooling status information can comprise equipment air intake temperature values, equipment airflow needs, and/or equipment power consumptions. The equipment cooling status information can be information that directly reflects the current cooling status of the equipment.

The equipment cooling status information can comprise equipment cooling status information collected by that equipment's own sensors. The equipment's own sensors collect equipment cooling status information. The equipment cooling status information collected by the equipment's own sensors can reflect the equipment's true cooling needs.

At 520, cooling of the equipment is controlled. The cooling control of the equipment can be performed based at least in part on the equipment cooling information.

The cooling control of the equipment is based at least in part on the equipment cooling information and can comprise cooling control of equipment based at least in part on equipment air intake temperature values, controlling of the fan speed of the cooling equipment based at least in part on equipment airflow need, cooling control of the equipment based at least in part on equipment power consumptions, or the like.

In some embodiments, cooling of equipment is controlled based at least in part on equipment air intake temperature values.

If the equipment air intake temperature values received at 510 correspond to the equipment's air intake temperature values collected by the equipment's own sensors (e.g., equipment air intake temperature values that have not undergone processing), then, before cooling control is implemented at 520, in accordance with equipment air intake temperature values, equipment air intake temperature values can be extracted so that equipment can be subjected to cooling control based on the extracted equipment air intake temperature values. The equipment air intake temperature values can be extracted according to process 200 or process 300. For example, one or more valid equipment air intake values can be used in connection with cooling control of the equipment.

In the event that cooling control is carried out based at least in part on the equipment air intake temperature values, the equipment air intake temperature values can be compared to the equipment air intake temperature settings, and in the event that an equipment air intake temperature value is less than said equipment air intake temperature setting, then the water valve opening is reduced. In the event that the equipment air intake temperature value is greater than the equipment air intake temperature setting, then the water valve opening can be enlarged.

The equipment air intake temperature settings can be the preferred equipment air intake temperature values that are set. The equipment air intake temperature settings can be set by an administrator or a manufacturer of the equipment. According to various embodiments, the equipment air intake temperature settings differ for different equipment.

If the equipment air intake temperature value is greater than the equipment air intake temperature setting, the cooling equipment is deemed to not satisfy equipment cooling needs. In the event that the equipment air intake temperature value is greater than the equipment air intake temperature setting, priority is given to enlarging the water valve opening (e.g., enlarging the opening of the coil valve of the cooling equipment). For example, in the event that the equipment air intake temperature value is greater than the equipment air intake temperature setting, cooling control can enlarge the water valve opening before performing cooling control using another cooling equipment or system. In the event that the water valve opening is 100% open, and the equipment air intake temperature value is still greater than the equipment air intake temperature setting, then the equipment air intake temperature can be adjusted by performing cooling control using another cooling equipment or system such as by increasing the fan speed.

If said equipment air intake temperature value is less than the equipment air intake temperature setting, then the water valve opening is reduced. If the equipment air intake temperature value is less than the equipment air intake temperature setting, the cooling equipment is deemed to be over-cooling. In the event that the equipment air intake temperature value is less than the equipment air intake temperature setting, the equipment air intake temperature can be adjusted by reducing the water valve opening.

The degree to which the water valve opening is enlarged or reduced in connection with cooling control may be set according to an empirical value. In some embodiments, the water valve opening can be iteratively adjusted (e.g., enlarged or reduced) at preset amounts based at least in part on a comparison of the equipment air intake temperature values after the adjustment to the equipment air intake temperature settings.

The power consumption of a fan is generally greater than the power consumption of a cooling coil. Accordingly, in some embodiments, cooling equipment will reduce fan speed to the minimum permissible speed that is set in the cooling process. If, in the event that the equipment air intake temperature value is less than the equipment air intake temperature setting, and the fan speed is not operating at the minimum permissible speed, then priority is given to lowering the fan speed. If, in cases where the minimum permissible fan speed has been reached, and the equipment air intake temperature value is still less than the equipment air intake temperature setting, then the water valve opening will be again reduced.

In some embodiments, the fan speed of cooling equipment is controlled based at least in part on equipment airflow need.

In the event that cooling control is carried out by controlling the fan speed of the cooling equipment based at least in part on equipment airflow need, the equipment airflow need is compared with current airflow supply of cooling equipment. In the event that equipment airflow need is greater than the current airflow supply of cooling equipment, then the fan speed is increased. Conversely, in the event that the equipment airflow need is less than the current airflow supply of cooling equipment, then the fan speed is reduced.

In some embodiments, the equipment airflow need is the total equipment airflow need of all equipment within the cooling equipment cooling control range. The received equipment cooling need information can comprise the total equipment airflow need of all equipment within the cooling equipment cooling control range. In the event that the received equipment cooling need information does not comprise the total equipment airflow need of all equipment within the cooling equipment cooling control range, the equipment airflow needs in the received equipment cooling need information are summed to obtain the total equipment airflow need, and the equipment airflow need total of all equipment in the cooling equipment cooling control range is compared with the current airflow supply of the cooling equipment. The current airflow supply of the cooling equipment can be obtained by acquiring cooling equipment rotation speed information and then relating cooling equipment rotation speed information to airflow supply.

In addition, if the equipment airflow need comprised in the received equipment cooling need information is unrevised equipment airflow need (e.g., equipment airflow need that has not been revised according to a safety factor), then the received equipment airflow need is revised before the equipment airflow need total of all equipment in the cooling equipment cooling control range is compared with the current airflow supply of the cooling equipment. A setting may be made in advance for equipment having corresponding equipment cooling status information to undergo processing. For example, equipment that acquires its own cooling status information can be preset to process the acquired cooling status information, in which case the cooling equipment does not subject the cooling need information to further processing after receiving the cooling need information. Conversely, if the cooling equipment is preset to process cooling status information, the equipment will, upon acquiring its own cooling status information, send the cooling status information directly to the cooling equipment. In response to the cooling equipment receiving the cooling status information, the cooling equipment will process the cooling status information.

In the event that the equipment airflow need is greater than the current airflow supply of cooling equipment, then the fan speed is increased. The fan speed of the cooling equipment directly affects equipment airflow need. Thus, if equipment airflow need is greater than the current airflow supply of the cooling equipment, the cooling equipment airflow supply is deemed to have failed to meet equipment airflow need. Therefore, in the event that equipment airflow need is determined to be greater than the current airflow supply of the cooling equipment, fan speed is increased to raise the airflow supply of the cooling equipment.

In the event that the equipment airflow need is less than the current airflow supply of cooling equipment, then the fan speed is reduced. If the equipment airflow need is less than the current airflow supply of cooling equipment, then the cooling equipment is deemed to be over-cooling. Therefore, the fan speed may be reduced in order to lower the airflow supply of the cooling equipment and to reduce cooling power consumption.

The degree to which the fan speed is increased or reduced may be set according to an empirical value. In some embodiments, the fan speed can be iteratively adjusted (e.g., increased or reduced) at preset amounts based at least in part on a comparison of the equipment airflow need with the current airflow supply of cooling equipment.

In some embodiments, cooling control of the equipment is controlled based at least in part on equipment power consumptions.

In some embodiments, an increase in power consumption generally indicates that equipment air intake temperature will rise. However, a time lag can exist between the increase in equipment power consumption and the rise in equipment air intake temperature. In the event that a percentage increase in equipment power consumption is assessed as having exceeded a specified percentage increase threshold value, the hazard arising from excessively high equipment air intake temperature can be prevented by first increasing the cooling output of the cooling equipment.

According to various embodiments, cooling control of the equipment, controlled based at least in part on equipment power consumptions, comprises calculating the percentage increases in equipment power consumption within the cooling equipment cooling control range, selecting power consumption percentage increases for a specific percentage of equipment in high-to-low order of the percentage increases in power consumption, and calculating the mean of the percentage increases in the specific selected percentage of equipment power consumptions. The mean of the percentage increases in the specific percentage of equipment power consumptions can be compared with a specified percentage threshold value to determine whether the mean of the percentage increases in the specific percentage of equipment power consumptions is greater than a specified percentage increase threshold value. In the event that the mean of the percentage increases in the specific percentage of equipment power consumptions is greater than a specified percentage increase threshold value, then the cooling equipment cooling output is increased.

The percentage increases in equipment power consumption of all equipment within the cooling equipment cooling control range are calculated according to Equation (1).

The power consumption percentage increases for a specific percentage of equipment is selected according tin an order from high-to-low of the percentage increases in power consumption. In some embodiments, only the equipment power consumption percentage increases of equipment with higher power consumption percentage increases are selected. For example, thirty percent of equipment power consumption percentage increases could be selected in high-to-low order of equipment power consumption percentage increases; forty percent of equipment power percentage increases could be selected; fifty percent of equipment power consumption percentage increases could be selected, or the like.

In some embodiments, in the event that the received equipment cooling need information comprises the equipment power consumptions of all equipment in the cooling control range, then the percentage increases in equipment power consumption within the cooling equipment cooling control range are calculated, the power consumption percentage increases for a specific percentage of equipment in high-to-low order of the percentage increases in power consumption are selected, and the mean of the percentage increases in the specific selected percentage of equipment power consumptions is calculated. In the event that the received equipment cooling need information comprises the mean of a specific percentage of equipment power consumption percent increases, then calculating the percentage increases in equipment power consumption within the cooling equipment cooling control range, selecting the power consumption percentage increases for a specific percentage of equipment in high-to-low order of the percentage increases in power consumption, and calculating the mean of the percentage increases in the specific selected percentage of equipment power consumptions can be omitted.

The mean of the percentage increases in the specific percentage of equipment power consumptions can be compared with a specified percentage threshold value to determine whether the mean of the percentage increases in the specific percentage of equipment power consumptions is greater than a specified percentage increase threshold value. In the event that the mean of the percentage increases in the specific percentage of equipment power consumptions is greater than a specified percentage increase threshold value, then the cooling equipment cooling output is increased.

According to various embodiments, in the event that the mean of percentage increases of a specific percentage in power consumption of a specific percentage of equipment exceeds a specified percentage increase threshold value, the corresponding equipment air intake temperature is expected to rise. Thus, in consideration of equipment safety, the cooling output of the cooling equipment can be increased in advance in order to prevent the hazards resulting from excessively high equipment air intake temperature.

In some embodiments, increasing the cooling output of the cooling equipment comprises enlarging the water valve opening and/or increasing fan speed.

In consideration of the need for equipment safety, upon discovering an excessively fast percentage rise in equipment power consumptions (e.g., whether the mean value of the percentage increase in the specific percentage of equipment power consumptions is greater than a specified percentage increase threshold value), the cooling output of the cooling equipment is increased in advance. When power consumption drops, the equipment air intake temperature will also drop. In such a situation, there is no risk of excessive air intake temperature. Thus, various embodiments impose no limitations on situations where equipment power consumption drops.

According to various embodiments, cooling control can include cooling control strategies (e.g., operations) that separately target equipment air intake temperature values and equipment airflow needs or equipment power consumptions. In some embodiments, any combination of the three cooling control strategies is executed simultaneously. The three cooling control strategies adjust fan speeds and water valve openings based on adjustment magnitudes that are set. The magnitude of adjustment can also be changed in accordance with current equipment cooling need information that is fed back in real time by equipment.

According to various embodiments, cooling control can be performed based on received equipment cooling need information. Because the cooling need information comprises equipment cooling status information or information obtained after processing the equipment cooling status information, and because the equipment cooling status information comprises the equipment cooling status information collected by the equipment's own sensors, the equipment cooling status information can therefore reflect the cooling needs of equipment directly and in real time. Thus, cooling control that is based on the equipment cooling need information can achieve need-based cooling and achieve control of final supply by final need feedback.

According to various embodiments, cooling control is performed by micro-modular control equipment (e.g., micro-modular data center equipment). The same device can perform each of the various operations associated with cooling control, or different devices can perform each of the various operations associated with cooling control.

FIG. 6 is a structural diagram of a cooling control device according to various embodiments of the present application. Device 600 can implement process 500 of FIG. 5. Device 600 can be used to implement system 700 of FIG. 7. In some embodiments, device 600 can be implemented by, or integrated with, computer system 900 of FIG. 9.

Device 600 comprises a receiving module 610 and a cooling control module 620.

The receiving module 610 is configured to receive equipment cooling information. In some embodiments, the receiving module is implemented as a communication interface such as a port, cable, wireline, or wireless network interface card, etc. The cooling information comprises equipment cooling status information. The cooling status information is acquired in real-time, periodically, or according to preset conditions (e.g., in the event that cooling satisfies a threshold level such as temperature). For example, equipment cooling status information can be acquired at fixed intervals of time. The cooling status information can comprise information that reflects the current cooling status (e.g., needs) of equipment.

The cooling status information can comprise equipment cooling status information, information obtained after processing the equipment cooling status information, or the like. The equipment cooling status information can comprise equipment air intake temperature values, equipment airflow needs, and/or equipment power consumptions. In addition, the equipment cooling status information can comprise equipment cooling status information collected by the equipment's own sensors.

The cooling control module 620 is configured to perform cooling control based at least in part on the equipment cooling need information.

The cooling control module 620 can comprise a first controlling sub-module 621, a second controlling sub-module 623, and a third controlling sub-module 625.

The first controlling sub-module 621 is configured to perform cooling control of equipment based at least in part on equipment air intake temperature values. The first controlling sub-module 621 can perform cooling control of equipment according to cooling control described in connection with process 500.

In some embodiments, the first controlling sub-module 621 includes a first comparing sub-module 622, a water valve opening adjustment sub-module 624, and a second controlling sub-module 623.

The first comparing sub-module 622 is configured to compare equipment air intake temperature values to the equipment air intake temperature settings and to obtain corresponding equipment air intake temperature value comparison results.

The water valve opening adjustment sub-module 624 is configured to adjust water valve openings according to the equipment air intake temperature value comparison results of the first comparing sub-module 622. In some embodiments, the water valve opening adjustment sub-module 624 is configured to enlarge the water valve opening in the event that the equipment air intake temperature value is greater than the equipment air intake temperature setting. In some embodiments, the water valve opening adjustment sub-module 624 is configured to reduce the water valve opening in the event that the equipment air intake temperature value is less than the equipment air intake temperature setting.

The second controlling sub-module 623 is configured to control the fan speeds of equipment based at least in part on equipment airflow needs. The second controlling sub-module 623 can control the fan speeds of equipment based at least in part on equipment airflow needs according to control of the fan speeds described in connection with process 500.

In some embodiments, the second controlling sub-module 623 includes a second comparing sub-module and a fan speed adjusting sub-module.

The second comparing sub-module is configured to compare the equipment airflow need with the current airflow supply of the cooling equipment and to obtain a corresponding equipment airflow need comparison result.

The fan speed adjusting sub-module is configured to adjust fan speed based at least in part on the equipment airflow need comparison result of the second comparing sub-module. In some embodiments, the fan speed adjusting sub-module increases fan speed in the event that the equipment airflow need is greater than the current airflow supply of cooling equipment. In some embodiments, the fan speed adjusting sub-module reduces fan speed in the event that the equipment airflow need is less than the current airflow supply of cooling equipment.

The third controlling sub-module 625 is configured to perform cooling control of the equipment based at least in part on equipment power consumptions. The third controlling sub-module 625 can perform cooling control based on equipment power consumptions according to cooling control described in connection with process 500.

In some embodiments, the third controlling sub-module 625 comprises a first calculating sub-module, a selecting sub-module, a second calculating sub-module, an assessing sub-module, and a cooling output adjusting sub-module.

The first calculating sub-module is configured to calculate the percentage increases in equipment power consumption within the cooling equipment cooling control range.

The selecting sub-module is configured to select power consumption percentage increases for a specific percentage of equipment in high-to-low order of the percentage increases in power consumption.

The second calculating sub-module is configured to calculate the mean of the percentage increases in the specific percentage of equipment power consumptions selected by the selecting sub-module.

The assessing sub-module is configured to determine whether the mean of the percentage increases in the specific percentage of equipment power consumptions is greater than a specified percentage increase threshold value.

The cooling output adjusting sub-module is configured to increase the cooling output of cooling equipment in the event that the assessing sub-module determines that the percentage increase in equipment power consumption is greater than a specified percentage increase threshold value.

According to various embodiments, the cooling control device is located on the same physical entity as the micro-modular data center cooling control equipment. In some embodiments, the cooling control device is located on a physical entity that is independent of the micro-modular data center cooling control equipment.

FIG. 7 is a structural diagram of a cooling control system according to various embodiments of the present application. System 700 can implement process 100 of FIG. 1, process 200 of FIG. 2, process 300 of FIG. 3, device 400 of FIG. 4, process 500 of FIG. 5, and device 600 of FIG. 6.

System 700 comprises to-be-cooled equipment 710 and cooling equipment 720.

The to-be-cooled equipment 710 acquires equipment cooling status information from the to-be-cooled equipment 710 itself and sends equipment cooling information to cooling equipment 720. The equipment cooling information can comprise the equipment cooling status information, or information obtained after processing the equipment cooling status information. The equipment cooling status information can comprise the to-be-cooled equipment's equipment cooling status information collected by the to-be-cooled equipment's own sensors. The equipment cooling status information can comprise equipment air intake temperature values, equipment airflow needs, and/or equipment power consumptions.

In some embodiments, the to-be-cooled equipment 710 includes IT equipment. In the case of IT equipment, its own sensors include intake/outlet temperature sensors set on motherboards, sensors that come with equipment such as CPUs, HDDs, VR, and DIMMs, and sensors that obtain airflow volumes based on “rotation speed airflow volume” test data fits.

The cooling equipment 720 is configured to receive equipment cooling need information and to perform cooling control of the to-be-cooled equipment 710 based at least in part on the equipment cooling information. The cooling equipment 720 can also be referred to as cooling control equipment. After receiving equipment cooling need information, the cooling equipment 720 can perform cooling control of to-be-cooled equipment based at least in part on a predetermined cooling strategy.

System 700 can further include data processing equipment 730. The processing equipment 730 is configured to process the equipment cooling status information acquired from to-be-cooled equipment 710 and to obtain processed equipment cooling status information. In some embodiments, the data processing equipment 730 can be incorporated into the to-be-cooled equipment 710. For example, the function of the data processing equipment 730 can be performed by the to-be-cooled equipment 710. In some embodiments, the data processing equipment 730 can be distinct from the to-be-cooled equipment 710.

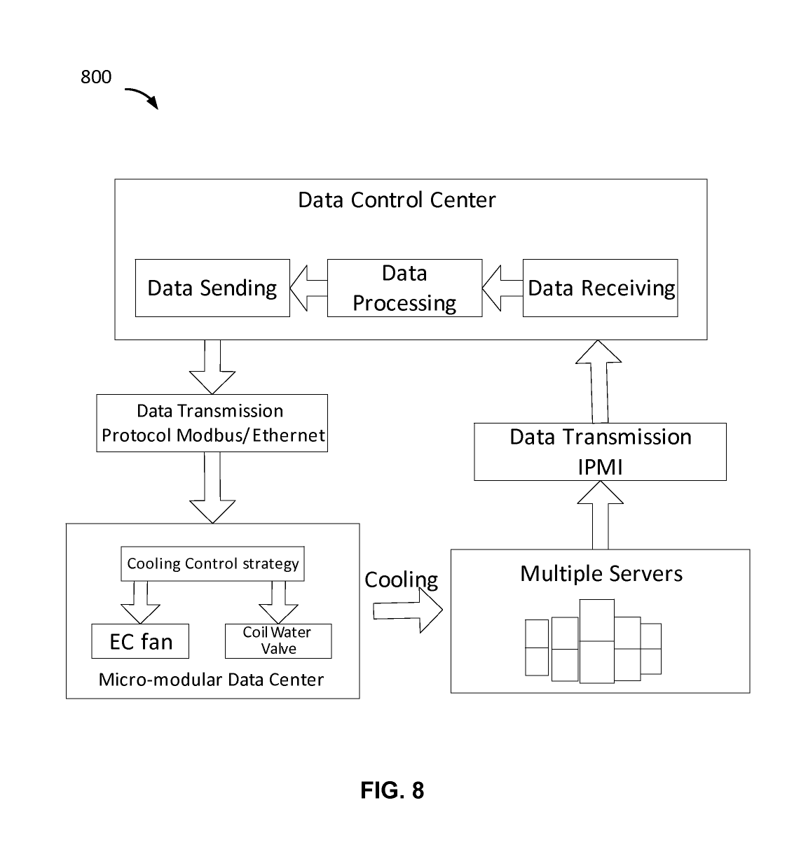

FIG. 8 is a framework and data flow diagram of a cooling control system according to various embodiments of the present application. Cooling control flow 800 can be implemented by process 100 of FIG. 1, process 200 of FIG. 2, process 300 of FIG. 3, or process 500 of FIG. 5.

Referring to FIG. 8, the to-be-cooled equipment corresponds to multiple servers, and the data processing equipment corresponds to a data control center. The cooling equipment can be a micro-modular data center. The multiple servers can have their own sensors which send the equipment cooling status information collected from the servers to the data control center. The collected equipment cooling status information can be sent via an Intelligent Platform Management Interface (IPMI) to the data control center.

After the data control center receives the equipment cooling status information, a predetermined data processing strategy is applied to process the received equipment cooling status information. Examples of the data processing strategy are to calculate and select equipment air intake temperature values according to process 200 of FIG. 2 or process 300 of FIG. 3, to revise the equipment airflow needs, and to calculate percentage increases in equipment power consumption. After the data is processed, the processed equipment cooling status information is sent as cooling need information to the cooling equipment. Different equipment cooling status information may be transmitted through different interfaces. As illustrated in FIG. 8, the industrial site bus protocol Modbus or Ethernet can be used to transmit the equipment cooling status information to the cooling equipment.

After the micro-modular data center receives the equipment cooling need information, the micro-modular data center performs cooling control of the to-be-cooled equipment in accordance with a preset cooling control strategy. Cooling control is mainly implemented by controlling the speed of the cooling equipment's electronically commutated (EC) fan and the opening of the cooling equipment's coil water valve. For example, a formula or process can be used to translate the temperature to the speed of a fan or a degree to which a valve is opened.

The modules (or sub-modules) described above can be implemented as software components executing on one or more general purpose processors, as hardware such as programmable logic devices and/or Application Specific Integrated Circuits designed to perform certain functions or a combination thereof. In some embodiments, the modules can be embodied by a form of software products which can be stored in a nonvolatile storage medium (such as optical disk, flash storage device, mobile hard disk, etc.), including a number of instructions for making a computer device (such as personal computers, servers, network equipment, etc.) implement the methods described in the embodiments of the present invention. The modules may be implemented on a single device or distributed across multiple devices. The functions of the modules may be merged into one another or further split into multiple sub-modules.

FIG. 9 is a functional diagram of a computer system for controlling cooling according to various embodiments of the present application.

Referring to FIG. 9, a computer system 900 for controlling cooling is provided. As will be apparent, other computer system architectures and configurations can be used to control cooling of equipment such as IT equipment. Computer system 900, which includes various subsystems as described below, includes at least one microprocessor subsystem (also referred to as a processor or a central processing unit (CPU)) 902. For example, processor 902 can be implemented by a single-chip processor or by multiple processors. In some embodiments, processor 902 is a general purpose digital processor that controls the operation of the computer system 900. Using instructions retrieved from memory 910, the processor 902 controls the reception and manipulation of input data, and the output and display of data on output devices (e.g., display 918).

Processor 902 is coupled bi-directionally with memory 910, which can include a first primary storage, typically a random access memory (RAM), and a second primary storage area, typically a read-only memory (ROM). As is well known in the art, primary storage can be used as a general storage area and as scratch-pad memory, and can also be used to store input data and processed data. Primary storage can also store programming instructions and data, in the form of data objects and text objects, in addition to other data and instructions for processes operating on processor 902. Also as is well known in the art, primary storage typically includes basic operating instructions, program code, data, and objects used by the processor 902 to perform its functions (e.g., programmed instructions). For example, memory 910 can include any suitable computer-readable storage media, described below, depending on whether, for example, data access needs to be bi-directional or uni-directional. For example, processor 902 can also directly and very rapidly retrieve and store frequently needed data in a cache memory (not shown). The memory can be a non-transitory computer-readable storage medium.

A removable mass storage device 912 provides additional data storage capacity for the computer system 900, and is coupled either bi-directionally (read/write) or uni-directionally (read only) to processor 902. For example, storage 912 can also include computer-readable media such as magnetic tape, flash memory, PC-CARDS, portable mass storage devices, holographic storage devices, and other storage devices. A fixed mass storage 920 can also, for example, provide additional data storage capacity. The most common example of mass storage 920 is a hard disk drive. Mass storage device 912 and fixed mass storage 920 generally store additional programming instructions, data, and the like that typically are not in active use by the processor 902. It will be appreciated that the information retained within mass storage device 912 and fixed mass storage 920 can be incorporated, if needed, in standard fashion as part of memory 910 (e.g., RAM) as virtual memory.

In addition to providing processor 902 access to storage subsystems, bus 914 can also be used to provide access to other subsystems and devices. As shown, these can include a display monitor 918, a network interface 916, a keyboard 904, and a pointing device 906, as well as an auxiliary input/output device interface, a sound card, speakers, and other subsystems as needed. For example, the pointing device 906 can be a mouse, stylus, track ball, or tablet, and is useful for interacting with a graphical user interface.

The network interface 916 allows processor 902 to be coupled to another computer, computer network, or telecommunications network using a network connection as shown. For example, through the network interface 916, the processor 902 can receive information (e.g., data objects or program instructions) from another network or output information to another network in the course of performing method/process steps. Information, often represented as a sequence of instructions to be executed on a processor, can be received from and outputted to another network. An interface card or similar device and appropriate software implemented by (e.g., executed/performed on) processor 902 can be used to connect the computer system 900 to an external network and transfer data according to standard protocols. For example, various process embodiments disclosed herein can be executed on processor 902, or can be performed across a network such as the Internet, intranet networks, or local area networks, in conjunction with a remote processor that shares a portion of the processing. Additional mass storage devices (not shown) can also be connected to processor 902 through network interface 916.

An auxiliary I/O device interface (not shown) can be used in conjunction with computer system 900. The auxiliary I/O device interface can include general and customized interfaces that allow the processor 902 to send and, more typically, receive data from other devices such as microphones, touch-sensitive displays, transducer card readers, tape readers, voice or handwriting recognizers, biometrics readers, cameras, portable mass storage devices, and other computers.

The computer system shown in FIG. 9 is but an example of a computer system suitable for use with the various embodiments disclosed herein. Other computer systems suitable for such use can include additional or fewer subsystems. In addition, bus 914 is illustrative of any interconnection scheme serving to link the subsystems. Other computer architectures having different configurations of subsystems can also be utilized.

In summary of the above, a cooling method, device, and system provided by embodiments of the present application can carry out cooling control based on equipment cooling need information. Because the equipment cooling information comprises: the equipment cooling status information or information obtained after processing the equipment cooling status information, and because the cooling status information comprises the equipment cooling status information collected by the equipment's own sensors, the cooling status information can therefore reflect the cooling needs of equipment directly and in real time. Thus, cooling control that is based on the equipment cooling information can achieve need-based cooling. The cooling control that is based on the equipment cooling information conserves energy while assuring that equipment cooling needs are met. Moreover, cooling control that is based on the equipment cooling information achieves control of final cooling supply by final need feedback.

A person skilled in the art should understand that the embodiments of the present invention can be provided as methods, systems or computer software products. Therefore, the present invention may take the form of complete hardware embodiments, complete software embodiments, or embodiments that combine software and hardware. Moreover, the present invention may take the form of computer program products implemented on one or more computer-operable storage media (including but not limited to magnetic disk storage, CD-ROMs, and optical storage) containing computer-operable program code.

The present invention is described with reference to flow charts and/or block diagrams based on methods, equipment (systems), and computer program products of the present invention. Please note that each flow chart and/or block diagram within the flowcharts and/or block diagrams and combinations of flow charts and/or block diagrams within the flowcharts and/or block diagrams can be realized by computer commands. One can provide these computer commands to a general-purpose computer, a specialized computer, an embedded processor, or the processor of other programmable data equipment so as to give rise to a machine, with the result that the commands executed through the computer or processor of other programmable data equipment give rise to a device that is used to realize the functions designated by one or more processes in a flow chart and/or one or more blocks in a block diagram.

These computer program commands can also be stored on specially-operating computer-readable storage devices that can guide computers or other programmable data equipment, with the result that the commands stored on these computer-readable devices give rise to commodities that include command devices. These command devices realize the functions designated in one or more processes in a flow chart and/or one or more blocks in a block diagram.

These computer program commands can also be loaded onto a computer or other programmable data equipment, with the result that a series of operating steps is executed on a computer or other programmable equipment so as to give rise to computer processing. In this way, the commands executed on a computer or other programmable equipment provide steps for realizing the functions designated by one or more processes in a flow chart and/or one or more blocks in a block diagram

In one typical configuration, the computation equipment comprises one or more processors (CPUs), input/output interfaces, network interfaces, and memory.

Memory may include such forms as volatile storage devices in computer-readable media, random access memory (RAM), and/or non-volatile memory, such as read-only memory (ROM) or flash memory (flash RAM). Memory is an example of a computer-readable medium.

Computer-readable media, including permanent and non-permanent and removable and non-removable media, may achieve information storage by any method or technology. Information can be computer-readable commands, data structures, program modules, or other data. Examples of computer storage media include but are not limited to phase-change memory (PRAM), static random access memory (SRAM), dynamic random access memory (DRAM), other types of random access memory (RAM), read-only memory (ROM), electrically erasable programmable read-only memory (EEPROM), flash memory or other memory technology, compact disk read-only memory (CD-ROM), digital versatile disc (DVD) or other optical storage, magnetic cassettes, magnetic tape or magnetic disc storage, or other magnetic storage equipment or any other non-transmission media that can be used to store information that is accessible to computers. As defined in this document, computer-readable media does not include temporary computer-readable media, (transitory media), such as modulated data signals and carrier waves.

Please also note that the term “comprise” or “contain” or any of their variants are to be taken in their non-exclusive sense. Thus, processes, methods, merchandise, or equipment that comprises a series of elements not only comprises those elements, but also comprises other elements that have not been explicitly listed or elements that are intrinsic to such processes, methods, merchandise, or equipment. In the absence of further limitations, elements that are limited by the phrase “comprises a(n) . . . ” do not exclude the existence of additional identical elements in processes, methods, merchandise, or equipment that comprises said elements.

A person skilled in the art should understand that embodiments of the present application can be provided as methods, systems, or computer program products. Therefore, the present application may take the form of complete hardware embodiments, complete software embodiments, or embodiments that combine software and hardware. Moreover, the present application may take the form of computer program products implemented on one or more computer-operable storage media (including but not limited to magnetic disk storage, CD-ROMs, and optical storage) containing computer-operable program code.

The above-stated are merely embodiments of the present application and do not limit the present application. For persons skilled in the art, the present application may have various modifications and variations. Any modification, equivalent substitution, or improvement made in keeping with the spirit and principles of the present application shall be included within the scope of the claims of the present application.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A method, comprising:
acquiring equipment cooling status information, wherein the equipment cooling status information is collected by a set of one or more sensors included in equipment to be cooled; and
sending equipment cooling information to cooling equipment to cause the cooling equipment to perform cooling control of the equipment to be cooled based at least in part on the equipment cooling information, wherein the equipment cooling information comprises at least part of the equipment cooling status information or information obtained after processing the equipment cooling status information or both.

2. The method of claim 1, wherein the equipment cooling status information comprises one or more of equipment air intake temperature values, equipment airflow needs, or equipment power consumptions.

3. The method of claim 1, wherein in the event that the equipment cooling status information includes equipment air intake temperature values, the acquiring of the equipment cooling status information comprises:
acquiring equipment air intake temperature values for at least some equipment within a cooling equipment cooling control range.

4. The method of claim 3, wherein the processing of the equipment cooling status information comprises:
determining valid equipment air intake temperature values from among the acquired equipment air intake temperature values;
selecting a specific percentage of equipment air intake temperature values from among the valid equipment air intake temperature values; and
calculating a mean of the specific percentage of equipment air intake temperature values that were selected.

5. The method of claim 3, wherein the processing of the equipment cooling status information comprises:
determining valid equipment air intake temperature values from among the acquired equipment air intake temperature values; and
selecting a maximum value from the valid equipment air intake temperature values.

6. The method of claim 3, wherein the processing of the equipment cooling status information comprises:
determining valid equipment air intake temperature values from among the acquired equipment air intake temperature values, wherein the determining of the valid air intake temperature values comprises:
determining abnormal equipment air intake temperature values among the acquired equipment air intake temperature values, wherein the abnormal equipment air intake temperature values comprise equipment air intake temperature values higher than an equipment air intake temperature value upper limit or equipment air intake temperature values lower than an equipment air intake temperature value lower limit; and
determining equipment air intake temperature values that are not abnormal equipment air intake temperature values to be valid equipment air intake temperature values; and
selecting one or more of the valid equipment air intake temperature values.

7. The method of claim 6, further comprising:
determining equipment faults associated with the set of one or more sensors or one or more fans included in the equipment, wherein the equipment faults are used to determine the abnormal equipment air intake temperature values.

8. The method of claim 1, wherein the sending of equipment cooling information to cooling equipment comprises:
sending the equipment cooling information of different equipment zones to cooling equipment in corresponding cooling equipment zones based at least in part on mappings between the equipment zones and the cooling equipment zones.

9. The method of claim 1, further comprising:
processing the equipment cooling status information in the event that the equipment cooling status information comprises an equipment airflow need, wherein the processing of the equipment cooling status information comprises revising the equipment airflow need that was acquired and obtaining a corresponding revised equipment airflow need.

10. The method of claim 1, further comprising:
processing the equipment cooling status information in the event that the equipment cooling status information comprises an equipment power consumption, wherein the processing of the equipment cooling status information comprises:
calculating percentage increases in equipment power consumption of equipment within a cooling equipment cooling control range; and
selecting power consumption percentage increases for a specific percentage of equipment from the percentage increases in power consumption.

11. The method of claim 1, wherein the cooling control of the equipment to be cooled performed by the cooling equipment in response to receiving the equipment cooling information comprises one or more of changing a fan speed of one or more fans of the cooling equipment, changing an opening of a water valve of the equipment to be cooled, or changing an output of the cooling equipment.

12. A device, comprising:
at least one processor configured to:
acquire equipment cooling status information, wherein the equipment cooling status information is collected by a set of one or more sensors included in the device; and
send equipment cooling information to cooling equipment to cause the cooling equipment to perform cooling control of the device based at least in part on the equipment cooling information, wherein the equipment cooling information comprises at least part of the equipment cooling status information or information obtained after processing the equipment cooling status information or both; and
a memory coupled to the at least one processor and configured to provide the at least one processor with instructions.

13. A method, comprising:
receiving equipment cooling information, the equipment cooling information comprising equipment cooling status information or information obtained after processing the equipment cooling status information or both, wherein the equipment cooling status information is collected by a set of one or more sensors included in equipment to be cooled; and
performing cooling control of the equipment to be cooled based at least in part on equipment cooling information.

14. The method of claim 13, wherein the equipment cooling status information comprises one or more of equipment air intake temperature values, equipment airflow needs, or equipment power consumptions.

15. The method of claim 14, wherein performing cooling control of the equipment based at least in part on the equipment cooling information specifically comprises:
performing cooling control of the equipment to be cooled based at least in part on one or more of equipment air intake temperature values, equipment airflow need, or equipment power consumptions.

16. The method of claim 15, wherein performing cooling control of the equipment to be cooled based at least in part on equipment air intake temperature values comprises:
comparing the equipment air intake temperature values to corresponding equipment air intake temperature settings;
in the event that an equipment air intake temperature value is greater than a corresponding equipment air intake temperature setting, enlarging a water valve opening; and
in the event that the equipment air intake temperature value is less than the corresponding equipment air intake temperature setting, reducing the water valve opening.

17. The method of claim 15, wherein performing cooling control of the equipment to be cooled based at least in part on equipment airflow need comprises:
comparing the equipment airflow need with a current airflow supply of cooling equipment;
in the event that the equipment airflow need is greater than the current airflow supply of the cooling equipment, increasing a fan speed; and
in the event that the equipment airflow need is less than the current airflow supply of the cooling equipment, reducing the fan speed.

18. The method of claim 15, wherein performing cooling control of the equipment to be cooled based at least in part on the equipment power consumptions comprises:
calculating percentage increases in equipment power consumption within a cooling equipment cooling control range;
selecting power consumption percentage increases for a specific percentage of equipment from the percentage increases in power consumption;
calculating a mean of the percentage increases in the specific selected percentage of equipment power consumptions;
determining whether the mean of the percentage increases in the specific percentage of equipment power consumptions is greater than a specified percentage increase threshold value; and
in the event that the mean of the percentage increases in the specific percentage of equipment power consumptions is greater than the specified percentage increase threshold value, increasing a cooling equipment cooling output.

19. A device, comprising:
at least one processor configured to:
receive equipment cooling information, the equipment cooling information comprising equipment cooling status information or information obtained after processing the equipment cooling status information or both, wherein the equipment cooling status information is collected by a set of one or more sensors included in equipment to be cooled; and
perform cooling control of the equipment to be cooled based at least in part on equipment cooling information; and
a memory coupled to the at least one processor and configured to provide the at least one processor with instructions.

20. A system, comprising equipment to be cooled and cooling equipment;
wherein the equipment to be cooled comprises at least one processor configured to: acquire equipment cooling status information, wherein the equipment cooling status information is collected by a set of one or more sensors included in the equipment to be cooled, and send equipment cooling information to cooling equipment to cause the cooling equipment to perform cooling control of the equipment to be cooled, based at least in part on the equipment cooling information, wherein the equipment cooling information comprises at least part of the equipment cooling status information or information obtained after processing the equipment cooling status information or both; and
wherein the cooling equipment comprises at least one processor configured to: receive equipment cooling information, the equipment cooling information comprising equipment cooling status information or information obtained after processing the equipment cooling status information or both, and perform cooling control of the equipment to be cooled based at least in part on equipment cooling information.

21. The system of claim 20, further comprising:
data processing equipment configured to process equipment cooling status information acquired from the equipment to be cooled.

22. A computer program product, the computer program product being embodied in a non-transitory computer readable storage medium and comprising computer instructions for:
acquiring equipment cooling status information, wherein the equipment cooling status information is collected by a set of one or more sensors included in equipment to be cooled; and
sending equipment cooling information to cooling equipment to cause the cooling equipment to perform cooling control of the equipment to be cooled based at least in part on the equipment cooling information, wherein the equipment cooling information comprises at least part of the equipment cooling status information or information obtained after processing the equipment cooling status information or both.
